(19) United States
(12) Patent Application Publication
(10) Pub. No.: US 2026/0068563 A1
(43) Pub. Date: Mar. 5, 2026

(54) PLASMA ASSISTED DEPOSITION AND ETCHING METHODS, AND RELATED PROCESSING CHAMBERS, SYSTEMS, AND APPARATUS

(71) Applicant: Applied Materials, Inc., Santa Clara, CA (US)

(72) Inventors: Yi YANG, San Jose, CA (US); Sean KANG, Santa Clara, CA (US); Alan HAYES, Santa Clara, CA (US); Jacob WATSON, Santa Clara, CA (US); Justin GAU, Santa Clara, CA (US); Srinivas D. NEMANI, Sunnyvale, CA (US)

(21) Appl. No.: 18/939,889

(22) Filed: Nov. 7, 2024

Related U.S. Application Data
(60) Provisional application No. 63/689,797, filed on Sep. 2, 2024.
(60) Provisional application No. 63/690,761, filed on Sep. 4, 2024.

(51) Int. Cl. H01L 21/3065; H01J 37/32; H01L 21/02

(52) U.S. Cl. CPC H01L 21/3065; H01J 37/32091; H01J 37/32449; H01J 2237/332; H01J 2237/334

(57) ABSTRACT

The present disclosure relates to methods for plasma assisted deposition and etching in semi-conductor processing, and related apparatuses and systems. In one or more embodiments, a method of substrate processing includes flowing a deposition composition over a substrate within a processing volume, the deposition composition including a deposition precursor. The method includes flowing an etchant composition over the substrate, the etchant composition including an etchant precursor flowed at a flow rate that is a ratio of 11:1 or less relative to a flow rate of the deposition precursor. The method includes supplying a plasma to the processing volume, depositing one or more layers on the substrate using the deposition composition, and etching the one or more layers using the etchant composition.

### CROSS-REFERENCE TO RELATED APPLICATION

This application claims the benefit of U.S. provisional patent application Ser. No. 63/689,797, filed Sep. 2, 2024, and U.S. provisional patent application Ser. No. 63/690,761, filed Sep. 4, 2024, both of which are herein incorporated by reference in their entireties.

### BACKGROUND

### Field

The present disclosure relates to methods for plasma assisted deposition and etching in semi-conductor processing, and related apparatuses and systems.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, operations (such as epitaxial deposition operations) can be long, expensive, and inefficient, and can have limited capacity and throughput. Operations can also be limited with respect to application modularity. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration. The activation of gases can be limited, for example, at relatively low processing temperatures for device production (such as complementary field-effect transistor (CFET) devices). Moreover, relatively higher processing temperatures can involve unintended dopant diffusion and/or hindered device performance. Additionally, processing can limited with respect to selectivity.

Therefore, a need exists for improved apparatuses and methods in semiconductor processing.

### SUMMARY

The present disclosure relates to methods for plasma assisted deposition and etching in semi-conductor processing, and related apparatuses and systems.

In one or more embodiments, a method of substrate processing includes flowing a deposition composition over a substrate within a processing volume, the deposition composition including a deposition precursor. The method includes flowing an etchant composition over the substrate, the etchant composition including an etchant precursor flowed at a flow rate that is a ratio of 11:1 or less relative to a flow rate of the deposition precursor. The method includes supplying a plasma to the processing volume, depositing one or more layers on the substrate using the deposition composition, and etching the one or more layers using the etchant composition.

In one or more embodiments, a method of substrate processing includes flowing a deposition composition over a substrate within a processing volume, and flowing an etchant composition over the substrate. The etchant composition is substantially free of hydrogen gas. The method include supplying a plasma to the processing volume, depositing one or more layers on the substrate using the deposition composition, and etching the one or more layers using the etchant composition.

In one or more embodiments, a non-transitory computer-readable medium storing instructions that, when executed by a processor, cause a plurality of operations to be conducted. The plurality of operations include flowing a deposition composition over a substrate within a processing volume, the deposition composition including a deposition precursor, and flowing an etchant composition over a substrate. The etchant composition includes an etchant precursor flowed at a flow rate that is a ratio of 11:1 or less relative to a flow rate of the deposition precursor. The plurality of operations include supplying a plasma to the processing volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a cross-sectional view of a film structure that includes doped semiconductor layers, according to one or more embodiments.

FIG. 3 is a schematic block diagram view of a method of substrate processing for semiconductor manufacturing, according to one or more embodiments.

FIG. 4 is a is a cross-sectional view of a film structure that includes doped semiconductor layers formed using the co-flow embodiment of the method, according to one or more embodiments.

FIGS. 5A-5D are cross-sectional views of a portion of the film structure corresponding to various stages of a sequential embodiment of the method, according to one or more embodiments.

FIG. 6A is a schematic side cross-sectional view of a device, according to one or more embodiments.

FIG. 6B is a schematic side cross-sectional view of the device with source or drain structures formed on the semiconductor fins, according to one or more embodiments.

FIG. 7 is a schematic isometric view of the device, according to one or more embodiments.

FIG. 8 is a graphical representation of the Chlorine (Cl) optical emission spectrometry (OES) of different process gas recipes, according to embodiments.

FIG. 9 is a graphical representation amorphous silicon etch selectivity to single crystalline silicon etch selectivity for different etchant gas recipes, according to embodiments.

FIG. 10 is a cross sectional image of a substrate after the method has been performed, according to one or more embodiments.

FIG. 11 illustrates a schematic cross-sectional view of a processing chamber, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to methods for plasma assisted deposition and etching in semi-conductor processing, and related apparatuses and systems. The deposition and etching can be selective, and can involve low temperature processing.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

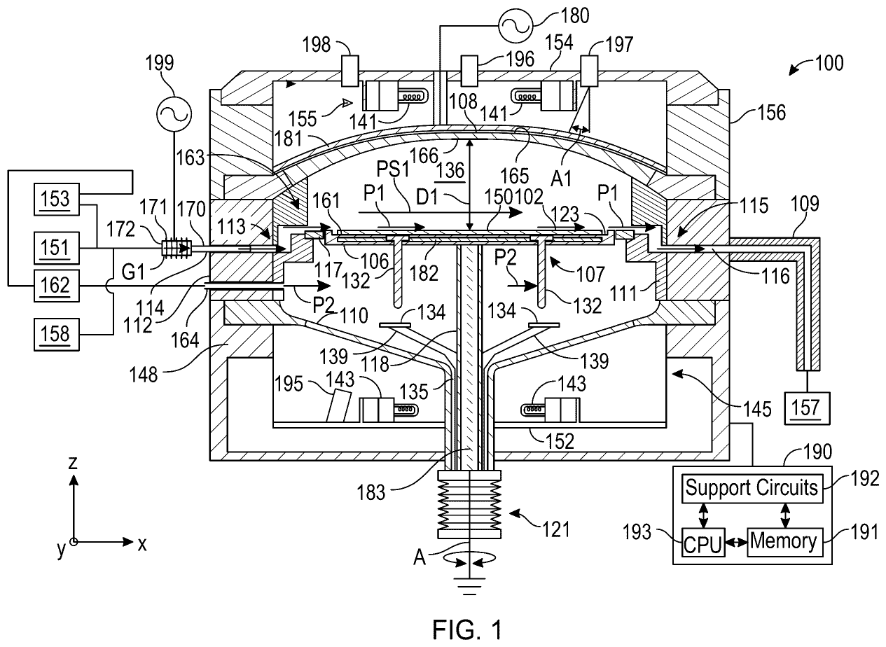

FIG. 1 is a schematic side cross-sectional view of a processing chamber 100, according to one or more embodiments. The processing chamber 100 is a deposition chamber. In one or more embodiments the processing chamber 100 is applicable for semiconductor manufacturing. In one or more embodiments, the processing chamber 100 is an epitaxial deposition chamber. The processing chamber 100 is utilized to grow an epitaxial film on a substrate 102, and the processing chamber 100 is used to supply a plasma for plasma operations (such as plasma-assisted film deposition, supply of ions into the substrate 102, pre-cleaning of the substrate 102, etching of the substrate 102, and/or cleaning of the processing chamber 100). In one or more embodiments, the processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, a plate 108, one or more heat sources 141, 143, and a window 110 (e.g., a lower window, for example a lower dome). In one or more embodiments, the window 110 is formed of an energy transmissive material, such as transparent quartz. In one or more embodiments, the plate 108 is a window, such as an upper window. In one or more embodiments, the plate 108 is an upper dome. In one or more embodiments, the plate 108 is formed of an energy transmissive material, such as transparent quartz. In one or more embodiments, the plate 108 if is formed at least partially of an opaque material such as opaque quartz (e.g., white quartz and/or grey quartz), black quartz, silicon carbide (SIC), graphite coated with SiC, and/or sapphire. In one or more embodiments, the plate 108 is a flat plate. In one or more embodiments, at least part of the plate 108 is curved. The one or more heat sources 141, 143 include a plurality of lower heat sources 143 operable to heat a processing volume 136 from one side of the substrate 102 (e.g., from below the substrate 102). In one or more embodiments, the one or more heat sources 141, 143 include a plurality of upper heat sources 141 operable to heat the processing volume 136 from a second side of the substrate 102 (e.g., from above the substrate 102). The chamber body and the plate 108 at least partially define the processing volume 136. In one or more embodiments, the lower heat sources 141, 143 include lamps (such as halogen lamps or UV lamps). The present disclosure contemplates that other heat sources may be used (in addition to or in place of the lamps) for the various heat sources described herein. For example, resistive heaters, microwave powered heaters, light emitting diodes (LEDs), lasers (e.g., laser diodes), and/or or any other suitable heat source singly or in combination may be used for the various heat sources described herein. In one or more embodiments the upper heat sources 141 are omitted such that the substrate 102 is heated from a back side using the lower heat sources 143.

The substrate support 106 is disposed in the processing volume 136 and between the plate 108 and the window 110. The substrate support 106 is disposed between the one or more heat sources 141, 143, and the substrate support 106 supports the substrate 102. The plate 108 is disposed between the substrate support 106 and a lid 154 of the processing chamber 100. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The upper heat sources are disposed between the lid 154 and the plate 108. The plurality of lower heat sources 143 are disposed between the window 110 and a floor 152. The plurality of lower heat sources 143 form a portion of a lower heat source module 145.

The processing volume 136 and a purge volume 138 are between the plate 108 and the window 110. The processing volume 136 and the purge volume 138 are part of an internal volume of the processing chamber 100. One or more liners 111, 163 are disposed inwardly of the chamber body.

The substrate support 106 includes a top surface on which the substrate 102 is disposed. The substrate support 106 is coupled to a shaft 118. In one or more embodiments, the substrate support 106 is coupled to the shaft 118 through one or more arms 119 coupled to the shaft 118. The shaft 118 is coupled to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 are part of an inject portion 113 of the chamber body, and the one or more gas exhaust outlets 116 are part of an exhaust portion 115 of the chamber body. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The pre-heat ring 117 can include a complete ring or one or more ring segments. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phosphine (PH₃), and the one or more cleaning gases include hydrochloric acid (HCl). In one or more embodiments, the one or more process gases P1 includes the one or more cleaning gases.

One or more gas sources 158 are also fluidly connected to the gas inlet(s) 114. The one or more gas sources 158 supply one or more plasma precursor gases that can be ignited into a plasma. A flow housing 171 is disposed at least partially outward of the flow module 112 and is fluidly connected to the flow module 112 through one or more flow channels 170 disposed between the flow housing 171 and the gas inlet 114. One or more radio frequency (RF) coils 172 is disposed at least partially around the flow housing 171. For example, the one or more RF coils 172 can be wound around the flow housing 171. As a gas G1 flows from the gas source 158 and through the flow housing 171, the one or more RF coils 172 ignite the gas G1 into a plasma PS1 which then flows through the one or more flow channels 170 and into the gas inlet 114. The one or more flow channels 170 can be formed, for example, in one or more gas boxes. RF current flows through the one or more RF coils 172 while the gas G1 flows, which applies a voltage across the gas G1 to ignite the gas G1 into the plasma PS1. The present disclosure contemplates that an ion filter can be positioned such that the ion filter filters ions from the plasma PS1 prior to the plasma PS1 flowing over the substrate 102. The ion filter can include a conductive material including, for example, silicon carbide (SiC), molybdenum, tungsten, stainless steel, and/or aluminum (such as anodized aluminum). The ion filter can include an ion blocker plate. The one or more gases G1 supplied using the one or more gas sources 158 can include one or more precursor gases to generate plasma such as Xenon (Xe₂), Neon (Ne₂), Helium (He₂) Fluorine (F₂), Krypton (Kr₂), and/or any mixtures of the thereof (such as Krypton Fluoride (KrF). In one or more embodiments, the gas G1 includes one or more silicon-containing gases (e.g., silane, dichlorosilane (DCS), trichlorosilane (TCS), disilane (DS), and/or tetraclorosilane) mixed with a carrier gas (e.g., argon, hydrogen, and/or helium). In one or more embodiments, the gas G1 includes one or more dopant gases, such as germane, diborane, and/or phosphorous. Other gases are contemplated for the gas G1. Other precursor gases are contemplated to generate the plasma PS1.

The processing chamber 100 includes a first electrode 181 between the plate 108 and the lid 154. In one or more embodiments, the first electrode 181 is disposed at a gap from the plate 108. The first electrode 181 can be at least partially supported by the lid 154 and/or the upper body 156. In one or more embodiments, the first electrode 181 is at least partially supported by an upper surface 165 of the plate 108. In one or more embodiments, the first electrode 181 has a mesh structure to allow at least part of electromagnetic radiation from the upper heat sources 141 to propagate through the mesh structure. In one or more embodiments, the first electrode 181 has a solid cross section. In one or more embodiments the first electrode 181 is made of an opaque material. In one or more embodiments the upper heat sources 141 are omitted. The first electrode 181 is electrically coupled to an RF power source 180. A second electrode 182 is coupled the substrate support 106. In one or more embodiments, the second electrode 182 is embedded in the substrate support 106. The substrate support 106 is grounded by a conductive rod 183 that connects the substrate support 106 to ground. In or more embodiments RF current flows from the first electrode 181, to the second electrode 182, and to ground through the conductive rod 183. In one or more embodiments, the RF current flows through one or more of: the plate 108, at least a section of the processing volume 136 and/or inner surface(s) of the liner 163. The gas G1 flows from into the processing volume 136 through the gas inlet 114. As the gas G1 flows into the processing volume 136 the gas G1 is ignited in a capacitively coupled plasma (CCP) manner by the RF current flowing between the first electrode 181 and the second electrode 182.

It is contemplated that plasma may be ignited using radiofrequency (RF) current (e.g., using an RF power source) and/or in another manner, such as using microwave generators (e.g., microwave coils and/or microwave antennas. The present disclosure contemplates that plasma may be generated using a remote plasma source (RPS), CCP generation, inductively coupled plasma (ICP) generation, or a combination thereof. Other plasma generation methods are contemplated.

The present disclosure contemplates that the RF current flow can be reversed such that the RF current can flow from the second electrode 182 and to the first electrode 181. The RF power ignites the gas G1 into a plasma PS1 as the gas G1 is passing through the processing volume 136. The size and position of the first electrode 181 and the second electrode 182 as well as the intensity the RF power applied to the first electrode 181 may be adjusted to determine where in the processing volume 136 the gas G1 becomes a plasma PS1, and the intensity of the plasma PS1. In one or more embodiments, the gas G1 is ignited by the RF power supplied to the first electrode 181 in conjunction with the one or more RF coils 172 disposed at least partially about the flow housing 171. In one or more embodiments, the one or more RF coils 172 are unpowered or are omitted, and the plasma PS1 is generated using the first and second electrodes 181, 182. In one or more embodiments, one of the RF coils 172 or the electrodes 181, 182 can be omitted such that the other generates plasma PS1. In one or more embodiments, the RF coils 172 and the electrodes 181, 182 are both included such that both generate plasma PS1.

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111.

During a deposition operation (e.g., an epitaxial growth operation), the one or more process gases P1 flow through the one or more gas inlets 114, through the one or more gaps, and into the processing volume 136 to flow over the substrate 102. The substrate 102 is disposed at a distance D1 within a range of about 5 mm to about 30 mm relative to the lower surface 166 of the plate 108 during processing.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The present disclosure contemplates that the plasma PS1 and the one or more process gases P1 can flow at least partially simultaneously or sequentially with respect to each other. In one or more embodiments during the cleaning operation the gas G1 is flowed through the flow housing 171 simultaneously with the process gases P1 (the gas G1 can be flowed with the process gases P1 or separately from the process gases P1), or before or after the flowing of the one or more process gases P1. The plasma PS1 may flow into the processing volume 136 before the processing gas P1 to pre clean the substrate 102. The plasma may flow into the processing volume 136 after the process gases P1 in order to clean the processing volume 136 after deposition operations. In one or more embodiments, the gas G1 flows simultaneously with the process gases P1 through the flow housing 171. In more than one embodiments, and as described above, the gas G1 is ignited into the plasma PS1 in the processing chamber by the RF power from the RF power source 180 flowing between the first electrode 181 and the second electrode 182. The plasma PS1 and the process gases P1 may flow into the processing volume 136 simultaneously where the plasma PS1 may assist in the deposition operation by facilitating activation of the process gas(es) P1 (e.g., by breaking bonds of the process gas(es) P1. The present disclosure contemplates that a voltage and/or a frequency of RF power applied to the one or more RF coils 172 and/or the first electrode 181 can be varied and/or pulsed. The frequency can involve a single frequency or multiple frequencies. The multiple frequencies can be combined. The processing chamber 100 includes one or more sensor devices 195, 196, 197, 198 (e.g., metrology sensors, and/or temperature sensors) configured to measure parameter(s) (e.g., temperature(s)) within the processing chamber 100 and/or metrology parameter(s) of the substrate 102). In one or more embodiments, the one or more sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, one or more of the sensor devices 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature. For example, one or more of the sensor devices 195, 196, 197, 198 can measure one or more gas parameters and/or one or more plasma parameters (such as ion density, electron temperature, electron density, ion energy and angle distribution, enthalpy, radical density, and/or absorption). In one or more embodiments, one or more of the sensor devices 195, 196, 197, 198 include a residual gas analyzer, an optical emission spectrometer, an enthalpy probe, a Langmuir probe, Faraday cup, and/or an absorption spectrometer.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

The present disclosure contemplates that all sensor devices can be disposed above the plate 108 and/or on or adjacent to the lid 154. For example, the one or more lower sensor devices 195 can be omitted.

Each sensor device 195, 196, 197, 198, can be a single-wavelength sensor device or a multi-wavelength (such as dual-wavelength) sensor device. In one or more embodiments, the processing chamber 100 includes any one, any two, or any three of the four illustrated sensor devices 195, 196, 197, 198. In one or more embodiments, the processing chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the pre-heat ring 117, the substrate support 106, and/or the liners 111, 163. As an example, one or more sensor devices 195, 196, 197, 198 can measure temperatures of the substrate 102 and/or the pre-heat ring 117, and power to the one or more heat sources 141, 143 and/or the energy source 176 can be controlled based on the measured temperatures (e.g., using a feedback control). As described the one or more sensor devices can include, for example pyrometers. In one or more embodiments, one or more thermocouples (e.g., proximity thermocouples) can be used in addition to or in place of the pyrometers, and power to the one or more heat sources 141, 143 and/or the energy source 176 can be controlled based on the measured temperatures (e.g., using a feedback control).

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power supplied to the one or more heat sources 141, 143, the one or more RF coils 172, and/or the first electrode 181, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations (such as operations of the method 300) described herein. The instructions stored on the memory, when executed, cause one or more of the operations (such as operations of the method 800) described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the one or more heat sources 141, 143 and/or the energy source 176, the deposition, the cleaning, the rotational position, the heating, and gas flow through the processing chamber 100 by providing an output to the controls for the sensor devices 195, 196, 197, 198, the one or more heat sources 141, 143 and/or the energy source 176, the process gas source 151, the purge gas source 162, the motion assembly 121, and/or the exhaust pump 157.

During processing the substrate 102 is heated to a target temperature within a range of 0 degrees Celsius to 1,500 degrees Celsius. In one or more embodiments, the target temperature is 250 degrees Celsius or higher, or 600 degrees Celsius or less. In one or more embodiments, the target temperature for the substrate 102 is within a range of 350 degrees Celsius to 600 degrees Celsius, for example 400 degrees Celsius to 500 degrees Celsius. In one or more embodiments, the target temperature for the substrate 102 is less than 500 degrees Celsius. In one or more embodiments, the target temperature for the substrate 102 is 400 degrees Celsius or less, such as less than 200 degrees Celsius (for example about 150 degrees Celsius).

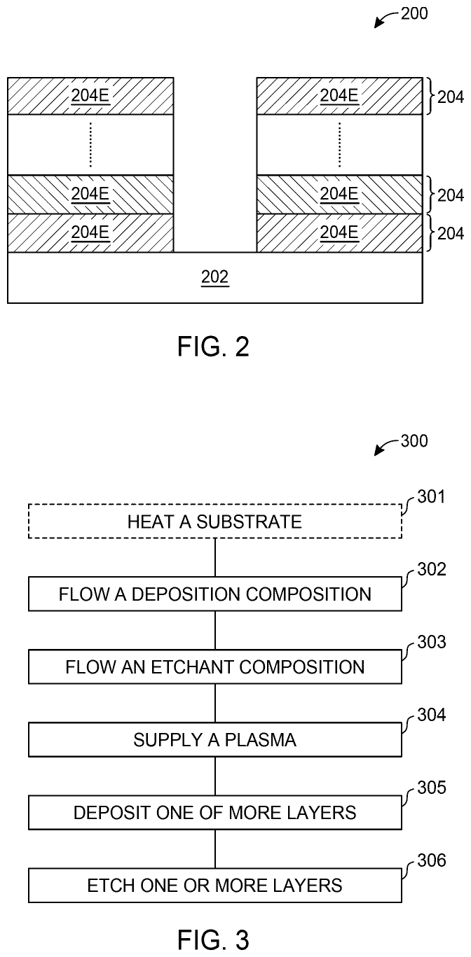

FIG. 2 is a cross-sectional view of a film structure 200 that includes doped semiconductor layers 204, according to one or more embodiments. In one or more embodiments, the film structure 200 is a semiconductor structure. Doped semiconductor layers 204, such as doped with n-type carrier dopants, such as phosphorous, may be used as a source/drain in n-channel metal-oxide semiconductor (NMOS) devices.

The film structure 200 includes a substrate 202, and a stack of doped semiconductor epitaxial layers 204 formed on the substrate 202. The substrate 202 can include a layer of material that serves as a basis for subsequent processing operations and includes a surface to be cleaned. The substrate 202 may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The doped semiconductor epitaxial layers 204 are formed of silicon (Si) or silicon germanium (SiGe) with a ratio of germanium (Ge) ranging between 20% and 100%. The doped semiconductor epitaxial layers 204 may be doped with n-type carrier dopants such as phosphorus (P) or antimony (Sb). The concentration can be between about 10¹⁹ cm⁻³ and 5·×10²¹ cm⁻³, depending upon the desired conductive characteristic of the film structure 200. The doped semiconductor epitaxial layers 204 may be doped with p-type carrier dopants such as boron (B), gallium (Ga), aluminum (Al), or indium (In). The concentration can be between about 1020 cm⁻³ and 5×·10²¹ cm⁻³, depending upon the desired conductive characteristic of the film structure 200.

The doped semiconductor epitaxial layers 204 may respectively have a thickness of between about 15 Å and about 20 Å. The film structure 200 may have about 30 doped semiconductor epitaxial layers 204, and can have a total thickness of between about 500 Å and about 700 Å, for example, about 600 Å.

In one or more embodiments, the doped semiconductor epitaxial layers 204 are cyclically formed by depositing a doped silicon layer and etching the doped silicon layer. In one or more embodiments, a single continuous epitaxial layer 204 is formed by flowing a deposition gas and an etchant gas simultaneously.

FIG. 3 is a schematic block diagram view of a method 300 of substrate processing for semiconductor manufacturing, according to one or more embodiments.

Optional operation 301 includes heating a substrate positioned on a substrate support of a processing chamber. The substrate is disposed in a processing volume of the processing chamber. The substrate can be heated from both sides or from one side of the substrate. The heating includes heating the substrate to a target temperature, such as the target temperature described above.

Operation 302 includes flowing a deposition composition over the substrate. In one or more embodiments, the deposition composition includes one or more of the reactive gases described in FIG. 1. In one or more embodiments, the deposition composition at least partially makes up a process gas.

Operation 303 includes flowing an etchant composition over the substrate. In one or more embodiments, the etchant composition includes one or more of the cleaning gases described in FIG. 1. In one or more embodiments, the etchant composition at least partially makes up a process gas. In one or more embodiments, operation 302 and 303 are preformed substantially simultaneously. In one or more embodiments, operations 302 and 303 are performed separately from one another.

Operation 304 includes supplying plasma to the processing volume. In one or more embodiments operation 304 further includes generating a plasma igniting a plasma precursor gas into a plasma by applying a power to a plasma precursor gas. The plasma can be ignited in a capacitively coupled plasma (CCP) manner or an inductively coupled plasma (ICP) manner. In one or more embodiments, a 600 W power is applied to a top of the processing volume (e.g., to the 181) to ignite the plasma precursor gas into a plasma. In one or more embodiments, a 1200 W power is applied to a side of the processing volume (e.g., to the coils 172 outside the processing volume in order to ignite the plasma precursor gas into a plasma. The plasma precursor gas can be ignited into the plasma in the processing volume 136 or in the flow housing 171. For example a plasma precursor gas can flow into the processing volume 136 shown in FIG. 1. An electrical power may then be applied to the electrode 181 disposed above the plate 108. In one or more embodiments, the plasma of operation 304 is supplied during the flowing of the deposition composition of operation 302, and the plasma flows over the substrate. The plasma activates the deposition composition. In one or more embodiments, the plasma of operation 304 is supplied before or after the flowing of the deposition composition of operation 302. In one or more embodiments, the plasma of operation 304 is supplied during the flowing of the etchant composition of operation 303, and the plasma flows over the substrate. The plasma activates the etchant composition. In one or more embodiments, the plasma of operation 304 is supplied before or after the flowing of the etchant composition of operation 303.

Operation 305 includes depositing one or more layers on the substrate using the deposition composition. In one or more embodiments, the plasma from operation 304 activates the deposition composition of operation 302 which causes the deposition composition to deposit one or more layers of deposition material on the substrate. The deposition composition can deposit both an single crystalline portion 204E and an amorphous and/or polycrystalline portion 204A, due to, for example, different nucleation rates of the doped semiconductor layer 204 on a surface of a semiconductor region (e.g., silicon (Si) or silicon germanium (SiGe)) of the substrate 202 and on a surface of a dielectric region (e.g., silicon dioxide (SiO₂) or silicon nitride (Si₃N₄)) of the substrate 202. The nucleation may occur at a faster rate on the surface of the semiconductor region than on the surface of the dielectric region, and thus an single crystalline portion 204E of the doped semiconductor layer 204 may be formed selectively on the surface of the semiconductor region while an amorphous and/or polycrystalline portion 204A of the doped semiconductor layer 204 may be formed on the surface of the dielectric region. The amorphous and/or polycrystalline portion 204A can be deposited and removed from, for example, a quartz (SiO₂) section of the substrate 202 and/or a dielectric (e.g., silicon nitride) section of the substrate 202.

In one or more embodiments, the deposition composition includes a deposition precursor. The deposition precursor includes a silicon-containing precursor, a germanium containing precursor, and/or a dopant source. The precursor gas(es) and/or the dopant(s) can be carried in a carrier gas (such as hydrogen gas and/or nitrogen gas). The silicon-containing precursor may include silane (SiH₄), disilane (Si₂H₆), trisilane, tetrasilane (Si₄H₁₀), dichlorosilane, trichlorosilane, silicon tetrachloride or a combination thereof. The germanium-containing precursor may include germane (GeH₄), germanium tetrachloride (GeCl₄), and digermane (Ge₂H₆). An n-type dopant source may include phosphine (PH₃), phosphorus trichloride (PCl₃), triisobutylphosphine ([(CH₃)₃C]₃P), antimony trichloride (SbCl₃), Sb(C₂H₅)₅, arsine (AsH₃), arsenic trichloride (AsCl₃), or tertiarybutylarsine (AsC₄H₁₁). A p-type dopant source may include diborane (B₂H₆), or boron trichloride (BCl₃). The n-type dopant source and/or p-type dopant source may include nitrogen (N₂), ammonia (NH₃), borane (BH₃) or disilabutane (C₂H₁₀Si₂), trisilapentane, trimethyl gallium (Ga(CH₃)₃), triethylgallium (Ga(C₂H₅)₃), aluminium chloride (AlCl₃), triethylaluminium (C₆H₁₅Al), trimethylaluminium (C₆H₁₈Al₂), methylsilane (CH₃SiH₃), indium chloride (InCl₃), gallium trichloride (GaCl₃), sodium oxalate (Na₂C₂O₄), trimethylindium ((CH₃)₃In), lithium triethylborohydride (LiBH(C₂H₅)₃), tris(trimethylsilyl)-arsine (As(TMS)₃), tertiarybutylarsine (TBAs), dibutyl sebacate (DBS), dioctylamine (DOA), myristic acid (MA), methyl myristate (MM), tri(di-tert-butylphosphino) gallane (Ga(PtBu₂)₃), hexadecylamine (HAD), indium acetate (In(Ac)₃), oleic acid (OA), 1-octadecene (ODE), 1-octylamine (OTA), palmitic acid (PA), tris(trimethylsilyl)-phosphine (P(TMS)₃), trioctylamine (TOA), trioctylphosphine (TOP), trioctylphosphine oxide (TOPO), bisazido dimethylaminopropyl gallium (BAZIGA), trimethylgallium (TMGa), trimethylaluminum (TMAl), triethylantimony (TESb), MoCl5 and/or TiCl as precursors.

Operation 306 includes etching one or more layers on the substrate using the etchant composition. In one or more embodiments, the plasma from operation 304 activates the etchant composition of operation 303 which causes the etchant composition to etch away one or more layers of deposition material over the substrate. The etchant composition includes an etchant precursor. The etchant precursor includes hydrogen chloride (HCl), chlorine gas (Cl₂) and/or fluorine containing etchants (such as carbon tetrafluoride (CF₄), fluoroform (CHF₃), difluoromethane (CH₂F₂), fluoromethane (CH₃F), and/or hexafluorodisilane (Si₂F₆)), or a combination thereof. The etchant composition may include a carrier gas such as argon (Ar), hydrogen gas (H₂), helium (He), or a combination thereof.

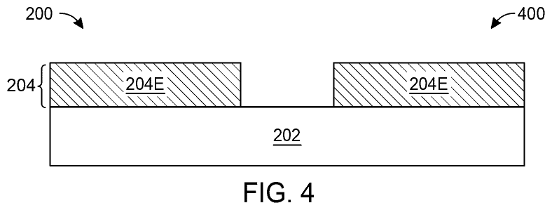

In one or more embodiments, at least part of operation 302 and at least part of operation 303 occur simultaneously in a co-flow embodiment 400 shown in FIG. 4. In the co-flow embodiment 400, the deposition composition and the etchant composition are flowed over the substrate substantially simultaneously. As previously described the deposition composition forms both a single crystalline portion 204E and an amorphous and/or polycrystalline portion 204A over the substrate 202. In the co-flow embodiment 400, the etchant composition etches away the amorphous and/or polycrystalline portion 204A of the semiconductor layer 204 while the portions 204A, 204E are deposited. The etching can remove polycrystalline portions of deposited layers. The one or more sections (e.g., the amorphous and/or polycrystalline portion 204A) are selectively etched relative to one or more other sections (e.g., single crystalline portions 204E). In one or more embodiments, a deposition rate of the amorphous and/or polycrystalline portion 204A is less than or equal to an etch rate of the amorphous and/or polycrystalline portion 204A so that the amorphous and/or polycrystalline portion 204A is in effect not deposited. The co-flow embodiment 400 results in one or more single crystalline portions 204E being continuously deposited without the amorphous and/or polycrystalline portion 204A being deposited. In one or more embodiments, the plasma of operation 304 is supplied during the flowing of the deposition composition and the etchant composition of the co-flow embodiment 400. The plasma activates at least one of the deposition composition or etchant composition.

In for example the co-flow embodiment 400, a ratio of the flow rate of the etchant composition to the flow rate of the deposition composition is 11:1 or less. In one or more embodiments, the ratio of the flow rate of the etchant precursor to the flow rate of the deposition precursor is 10:1 or less. In one or more embodiments, the deposition composition and/or the etchant composition include a carrier gas. In one or more embodiments, the carrier gas includes hydrogen gas (H₂). In one or more embodiments, the ratio of a flow rate of the hydrogen gas to a ratio of the flow rate of the etchant precursor is 1:10 or less. In one or more embodiments, the etchant composition and/or the deposition composition are substantially free of hydrogen gas (H₂). The present disclosure contemplates that the composition(s) can include hydrogen atoms and be substantially free of hydrogen gas. For example, the deposition composition can include phosphine (PH₃) and be substantially free of hydrogen gas. In one or more embodiments, a flow rate of hydrogen gas in the etchant composition is less than 100 sccm, such as less than 20 sccm, for example 5 sccm or less. The relatively low amount of hydrogen gas increases the etch selectivity of the amorphous and/or polycrystalline portion 204A. In one or more embodiments, a pressure of the processing volume is less than 100 mTorr (such as 10 mTorr) during the co-flow embodiment 400. DCS, HCl, and PH₃ can be flowed into the processing volume simultaneously for 20 seconds to 40 seconds, such as about 30 seconds. A ratio of the flow rate of DCS to the flow rate of HCl to the flow rate of PH₃ is 1:10:1.

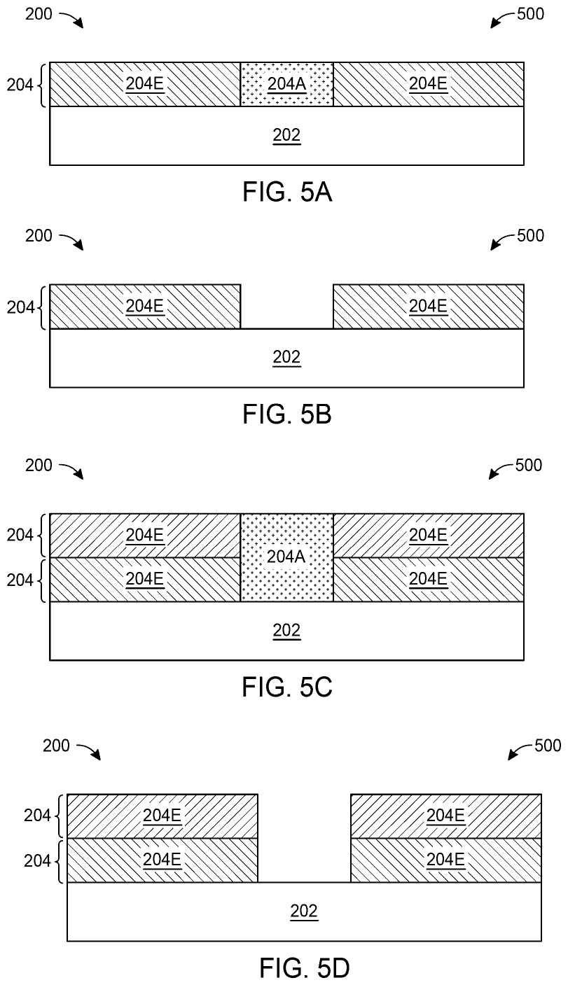

In one or more embodiments, the co-flow embodiment 400 of the method 300 has a processing temperature of 0 degrees Celsius to 1500 degrees Celsius, such as 400 degrees Celsius. The pressure within the process chamber is during the co-flow embodiment 400 is from about 1 mTorr to about 500 mTorr, such as about 10 mTorr. The flow rate of the deposition precursor is from about 0.5 sccm to about 100 sccm. In one or more embodiments, the flow rate of the deposition precursor is within a range of 1.0 sccm to 20 sccm. The flow rate of the etchant precursor is from about 0.5 sccm to about 100 sccm. In one or more embodiments, the flow rate of the etchant precursor is within a range of 50 sccm to 150 sccm. In one or more embodiments, operation 302 and operation 303 occur separately from one another in a sequential embodiment 500 shown in FIG. 5. In the sequential embodiment 500, the deposition composition of operation 302 deposits both an single crystalline portion 204E and an amorphous and/or polycrystalline portion 204A in operation 305, due to, for example, different nucleation rates of the doped semiconductor layer 204 on a surface of a semiconductor region (e.g., silicon (Si) or silicon germanium (SiGe)) of the substrate 202 and on a surface of a dielectric region (e.g., silicon dioxide (SiO₂) or silicon nitride (Si₃N₄)) of the substrate 202. The nucleation may occur at a faster rate on the surface of the semiconductor region than on the surface of the dielectric region, and thus an single crystalline portion 204E of the doped semiconductor layer 204 may be formed selectively on the surface of the semiconductor region while an amorphous and/or polycrystalline portion 204A of the doped semiconductor layer 204 may be formed on the surface of the dielectric region. In one or more embodiments, operation 302 includes flowing the deposition composition for a deposition time period that is 5 seconds or higher, such as 10 seconds or higher, such as 100 seconds or higher, such as 110 seconds to 130 seconds, for example 120 seconds. In one or more embodiments, a pressure of the processing volume is less than 100 mTorr (such as 10 mTorr) during the sequential embodiment 500. In one or more embodiments at operation 302 of the sequential embodiment 500, DCS, HCl, H₂, and PH₃ are flowed into the processing volume simultaneously for about 5 seconds to 15 seconds, such as about 10 seconds. A ratio of the flow rate of DCS to the flow rate of HCl to the flow rate of H₂ to the flow rate of PH₃ is 1:1:200:10. In one or more embodiments, the plasma of operation 304 is supplied during the flowing of the deposition composition of operation 302 and/or during the flowing of the etchant composition of operation 303, and the plasma flows over the substrate. The plasma activates the deposition composition and/or the etchant composition.

The present disclosure contemplates that two or more of the operations 301-306 of the method 300 (such as all of the operations 301-306) can be conducted in the same processing chamber. As an example for the sequential embodiment 500, the deposition of operations 302, 305 and the etching of operations 303, 306 can be sequentially repeated (e.g., deposition then etching then deposition then etching) in-situ in the same processing volume of the same processing chamber (such as processing chamber 100 or the processing chamber 1100). In such an example, the sequential deposition then etching can be conducted in the same plasma epitaxial deposition chamber. As described herein, the plasma may be generated and supplied using a variety of apparatus. For example, the plasma can be generated in-situ in the processing volume of the processing chamber (such as in a CCP manner or an ICP manner), and/or the plasma can be generated outside of the processing volume chamber by igniting the plasma precursor gas in a remote plasma source and flowing the plasma into the processing volume.

In the sequential embodiment 500, after operation 305 has been performed, the etchant composition of operation 303 is flowed over the substrate. In one or more embodiments, the etchant composition the etchant precursor such as chlorine gas (Cl₂) gas and a carrier gas (such as argon gas). The etching of the etch process includes flowing the etchant composition for an etchant time period and at an etchant flow rate. The etchant time period can be equal to or greater than the time period of the deposition. In one or more embodiments, the etchant time period is about 200 seconds. In one or more embodiments, a pressure of the processing volume is greater than 30 mTorr (such as 50 mTorr) during the sequential embodiment 500. In one or more embodiments at operation 303 of the sequential embodiment 500, Cl₂ and Ar are flowed into the processing volume simultaneously for more than 60 seconds, such as about 200 seconds. A ratio of the flow rate of Cl₂ to the flow rate of Ar is 1:30.

The etch composition of the operation 303 etches one or more sections of the one or more layers. In one or more embodiments, the one or more sections are amorphous and/or polycrystalline, such as an amorphous and/or polycrystalline portion 204A of the doped semiconductor layer 204, as shown in FIG. 5B. The one or more sections (e.g., the amorphous and/or polycrystalline portion 204A) are selectively etched relative to one or more other sections (e.g., single crystalline portions 204E).

In one or more embodiments a ratio of the flow rate the etchant precursor to the flow rate of the carrier gas is less than or equal to 50:600 such as 25:600. In one or more embodiments the ratio of a flow rate of the deposition precursor to the flow rate of the etchant precursor is less than 1:11, for example less than 1:20, such as 1:5 or 1:2.5. In one or more embodiments, the etchant precursor has a flow rate of about 0.5 sccm to about 100 sccm. In one or more embodiments, the flow rate of the etchant precursor is within a range of 10 sccm to 60 sccm, such as 15 sccm to 35 sccm, for example 20 sccm to 30 sccm. In one or more embodiments the carrier gas has a flow rate of about 0.5 sccm to about 1000 sccm. The etch selectivity of the amorphous and/or polycrystalline portion 204A to single crystalline portion 204E is about 90:1. In one or more embodiments, the flow rate of the deposition precursor is within a range of 1.0 sccm to 20 sccm. In one or more embodiments, of the sequential embodiment 500, operations 302 and 303 can be repeated to form a plurality of layers over the substrate. It is contemplated that operations 302 and 303 can be repeated until the desired thickness of the single crystalline portion 204E of the doped semiconductor layer 204 is reached. The overall thickness can be, for example, within a range of 500 Å to 700 Å, for example, 600 Å. The cycle (including sequentially operations 302, 303) may be repeated one or more additional times for a plurality of cycles. In one or more embodiments, etchant composition of operation 303 begins to flow after the flowing of the deposition composition of operation 302 ends.

In one or more embodiments, in the co-flow embodiment 400 and/or the the sequential embodiment 500, the ratio of the flow rate of the deposition precursor (e.g., a silicon containing precursor) to the flow rate of the etchant precursor is from 1:100 to 1:0.5. In one or more embodiments, the etchant precursor includes HCl, and the ratio of the flow rate of the deposition precursor to the flow rate of the etchant precursor is from 1:100 to 1:5. In one or more embodiments, the etchant precursor includes chlorine (Cl₂) and the ratio of the flow rate of the deposition precursor to the flow rate of the etchant precursor is from 1:10 to 1:0.5. The embodiments described herein can provide methods and systems for forming a contact epitaxial layer within a trench on a selected portion of a transistor structure. The layers formed may be n-type MOS (e.g., silicon) layers formed on an n-type MOS device. The doped silicon layers can be used as source/drain in a NMOS device.

The present disclosure contemplates that the operations and methods described herein may use plasma. For example, the deposition of operation 305 and/or the etching of operation 306 may use the plasma of operation 304 to facilitate the activation of gases to assist in deposition and/or etching. As an example, nitrogen gas and/or hydrogen gas may be used to ignite the plasma PS1. Other plasma compositions are contemplated. The plasma PS1 may be generated using a variety of apparatus. For example, the plasma PS1 can be generated in the processing volume 136 in a capacitive-coupled (CCP) manner or an inductive-coupled (ICP) manner. As another example, the plasma can be generated in the flow housing 171 and can be supplied into the processing volume 136 from a side of the processing chamber 100 or a top of the processing chamber 100. For example, the plasma can be supplied from the side of the processing chamber 100 through the same gas flow path as the process gases P1 (e.g., through the same gas inlets 114).

FIG. 4 is a is a cross-sectional view of a film structure 200 that includes doped semiconductor layers 204 formed using the co-flow embodiment 400 of the method 300, according to one or more embodiments. The single crystalline portions 204E of the one or more doped semiconductor layers 204 are formed by depositing the deposition composition on the substrate 202. The amorphous and/or polycrystalline portions 204A are in effect not formed because the etchant composition is flowed simultaneously to the deposition composition. The etchant composition selectively etches the amorphous and/or polycrystalline portions 204A as the amorphous and/or polycrystalline portions 204A are deposited.

FIGS. 5A-5D are cross-sectional views of a portion of the film structure 200 corresponding to various stages of a sequential embodiment 500 of the method 300, according to one or more embodiments.

FIG. 5A shows the film structure 200 after operation 302 has been performed. The deposition composition of operation 302 deposited both single crystalline portions 204E and amorphous and/or polycrystalline portions 204A of the one or more doped semiconductor layers 204.

FIG. 5B shows the film structure 200 after operation 303 has been performed. The etchant composition of operation 303 selectively etched away the amorphous and/or polycrystalline portions 204A of the one or more doped semiconductor layers 204 at a fast rate than the single crystalline portions 204E. The etchant composition is flowed until the amorphous and/or polycrystalline portion 204A is completely etched away.

FIG. 5C shows the film structure 200 after operation 302 has been repeated on the film structure 200 shown in FIG. 5B. The deposition composition of operation 302 deposited both single crystalline portions 204E and amorphous and/or polycrystalline portions 204A of the one or more doped semiconductor layers 204.

FIG. 5D shows the film structure 200 after operation 303 has been repeated on the film structure 200 shown in FIG. 5C. The etchant composition of operation 303 selectively etched away the amorphous and/or polycrystalline portions 204A of the one or more doped semiconductor layers 204 at a fast rate than the single crystalline portions 204E. The etchant composition is flowed until the amorphous and/or polycrystalline portion 204A is completely etched away.

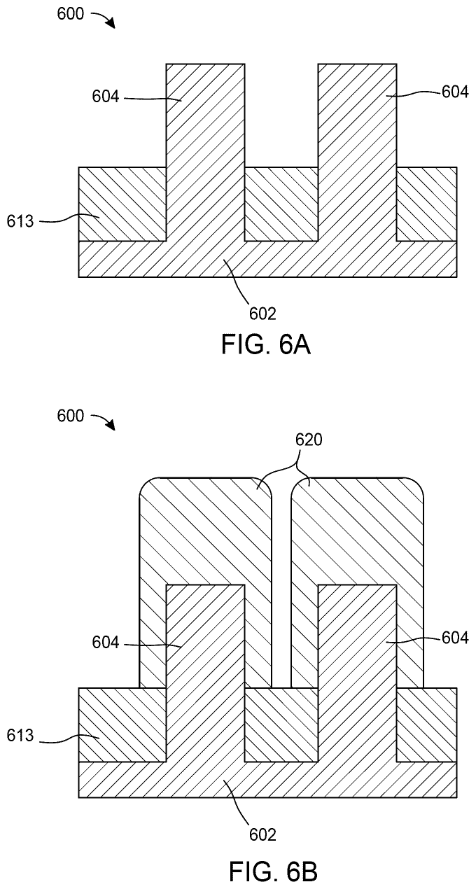

FIG. 6A is a schematic side cross-sectional view of a device 600, according to one or more embodiments. The device 600 includes a substrate 602, semiconductor fins 604 formed on the substrate 602, and dielectric material 613 between the semiconductor fins 604. In one or more embodiments, the fins 604 include one or more of silicon, silicon germanium, or germanium.

FIG. 6B is a schematic side cross-sectional view of the device 600 with source or drain structures 620 formed on the semiconductor fins 604, according to one or more embodiments. The source or drain structures 620 include the doped semi-conductor layers 204 formed using the method 300.

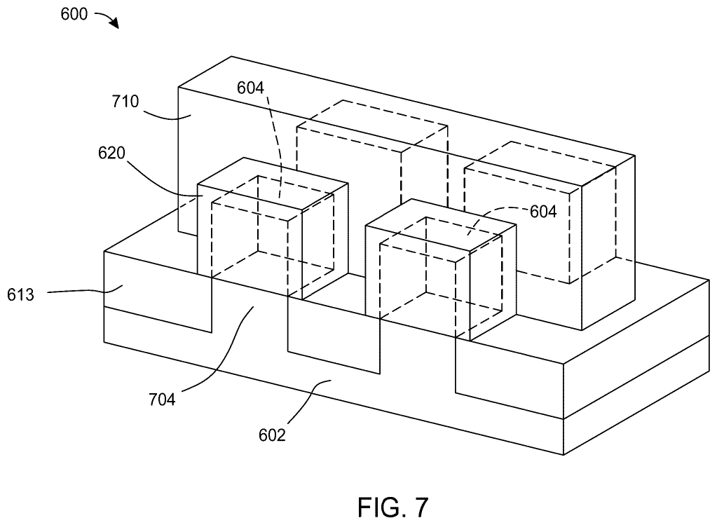

FIG. 7 is a schematic isometric view of the device 600, according to one or more embodiments. FIG. 7 further includes a gate electrode 710 between the fins 604 and on the dielectric material 613. The present disclosure contemplates that sections 704 of the fins 604 can extend upwardly past an upper surface of the dielectric material 613 and into the source or drain structures 620. In one or more embodiments, a material is disposed between the source or drain structures 620 and the gate electrode 710. In one or more embodiments, the material is a gate dielectric. In one or more embodiments, the material includes one or more of silicon dioxide, silicon nitride, silicon carbonitride, or silicon oxycarbonitride. In one or more embodiments, the plurality of source or drain structures 620 include a plurality of source structures 620 on one side of the gate electrode 710 and a plurality of drain structures 620 on another side of the gate electrode 710.

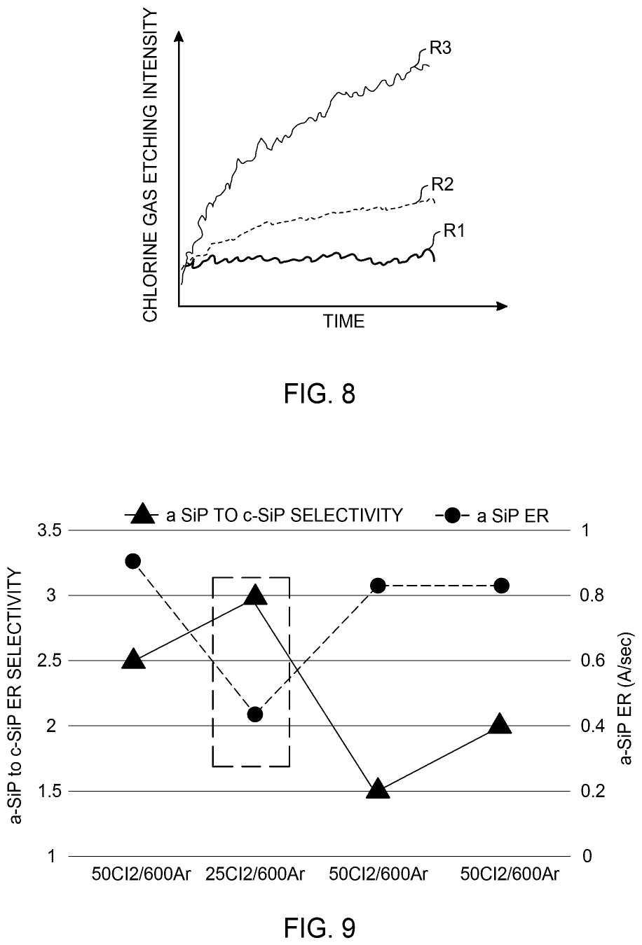

FIG. 8 is a graphical representation of the chlorine gas etching intensity for different process gas recipes, according to one or more embodiments. The process gas recipes shown in FIG. 8 can be used in the co-flow embodiment of the method 300. Process gas recipes R1, R2, R3 respectively include dichlorosilane (DCS), phosphine (PH₃), and hydrogen chloride gas (HCl). In one or more embodiments, the ratio of dichlorosilane (DCS) to phosphine (PH₃) to hydrogen chloride gas (HCl) is 10:10:100. In one or more embodiments, the process gas recipes R1, R2, R3 respectively can include hydrogen gas (H₂). The first process gas recipe R1 has a HCl:H₂ ratio of 0.5. The second process gas recipe R2 has a HCl:H₂ ratio of 1. The third process gas recipe R1 has a HCl:H₂ ratio of 0.5. The third process gas recipe R3 has a HCl:H₂ ratio greater than 1. In one or more embodiments, the third process gas recipe R3 is substantially free of hydrogen gas H₂. The third process gas recipe R3 has a greater Cl intensity than the second process gas recipe R2. The second process gas recipe R2 has a greater intensity than the first process gas recipe R1. A higher Cl intensity corresponds to a higher etch selectivity ratio of an etch rate of amorphous silicon to an etch rate of single crystalline silicon.

FIG. 9 is a graphical representation amorphous silicon phosphide etch selectivity to single crystalline silicon phosphide etch selectivity for different etchant composition recipes, according to one or more embodiments. The graph shows various etchant composition recipes and corresponding etch selectivity ratio of amorphous silicon to single crystalline silicon etch selectivity.

The etchant composition recipes shown in FIG. 9 can be used in the sequential embodiment 500 of the method 300. The etchant gas recipe with the highest etch selectivity ratio includes 25 sccm of a flow rate of Cl₂ gas to 600 sccm of a flow rate of Ar gas at a pressure of 50 mTorr and a power of 1800 Watts. This etchant gas recipe has an etch selectivity ratio of about 3. The amorphous etch rate of the etchant gas recipe is about 2.1. In one or more embodiments, the flow rate of Cl₂ gas is within a range of 15 sccm to 35 sccm, such as 20 sccm to 30 sccm, for example about 25 sccm.

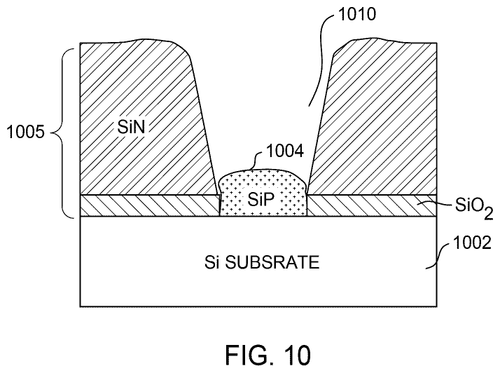

FIG. 10 is a cross sectional image of a substrate 1002 after the method 300 has been performed, according to one or more embodiments. The substrate 1002 includes a dielectric layer 1005. In one or more embodiments the dielectric layer includes a layer of silicon nitride (SiN) and a layer of silicon oxide (SiO₂) deposited over the substrate 1002. A channel 1010 is formed in the SiN layer. A single crystalline structure 1004 is formed within the channel 1010 on an upper surface of the substrate 1002. Due to different nucleation rates the single crystalline structure 1004 is formed on the upper surface of the substrate 1002 which is formed of silicon (Si) or silicon germanium (SiGe). The dielectric layer 1005 promotes the growth of amorphous silicon and/or polycrystalline silicon, rather than single crystalline silicon. The nucleation may occur at a faster rate on the upper surface of the substrate 1002 than on the surface of the dielectric layer 1005, and thus a single crystalline epitaxial structure 1004 may be formed selectively on the upper surface of the substrate 1002 while an amorphous portion layer and/or a polycrystalline portion layer may be formed on the surface of the dielectric layer 1005. The etchant operation 306 of method 300 selectively etches the amorphous layer and/or the polycrystalline portion layer deposited over the dielectric layer 1005 leaving the single crystalline structure 1004 within the channel 1010.

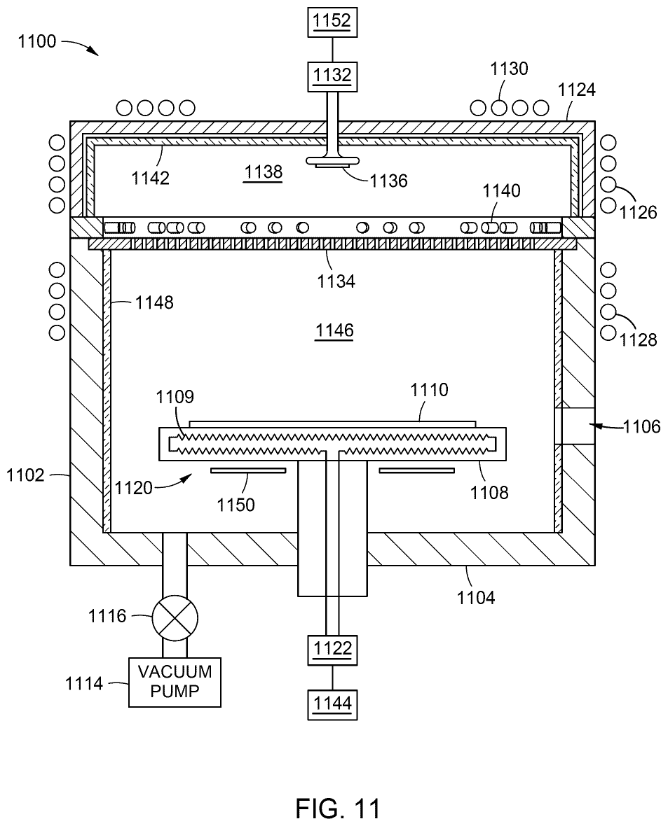

FIG. 11 illustrates a schematic cross-sectional view of a processing chamber 1100 according to one or more embodiments. The processing chamber 1100 is operable to deposit an EPI layer at a low temperature. The processing chamber 1100 in FIG. 11 includes side walls 1102, a bottom 1104, a chamber lid 1124, and a plurality of internal liners, including an upper lid liner 1142 and a lower wall liner 1148. The chamber lid 1124, the side walls 1102, and the bottom 1104 together enclose a processing region 1146. A susceptor 1120 is disposed in the processing region 1146 and supports a substrate 1110 thereon during processing. The side walls 1102 include a plurality of ports 1106 for transferring the substrate 1110 in or out of the processing chamber 1100. The upper lid liner 1142 and the lower wall liner 1148 are configured to insulate the lid 1124 and the side walls 1102, respectively, from the internal heat. According to an embodiment, the chamber lid 1124 may be made of metal, such as aluminum or stainless steel, and the upper lid liner 1142 and the lower wall liner 1148 may be made of thermal insulators, such as ceramic or quartz. The liners are configured to conform to the shape of the lid 1124 and the side walls 1102. Other liners, such as a gas ring liner may also be utilized to protect other components of the processing chamber 200.

The processing chamber 1100 includes a vacuum pump 1114 and a plurality of gas sources 1132 containing a carrier gas, a deposition gas, a purge gas, and a cleaning gas. The gases may be provided into the processing chamber via a gas feed. The gas feed may include a top baffle 1136 disposed at a central part of the lid 1124 and a plurality of side nozzles 1140 disposed along side walls of the lid 1124. The remote plasma source 1152 may be coupled with the gas feed of one or more of the gas sources 1132 and configured to energize each process gas independently or energize a mixture of two or more of the process gases. The energized process gas is provided to the chamber 1100 via the top baffle 1136. The vacuum pump 1114 is coupled to the processing chamber 1100 and configured to adjust the vacuum level within the process region 1146 via a valve 1116. Vacuum pump 1114 is also configured to evacuate spent gases from the processing chamber 1100. According to an embodiment, the wall liners 1148 includes an open lower end configured to allow process gases to flow through.

Optionally, the processing chamber 1100 also includes a gas plenum 1138 contained and a showerhead 1134. The gas sources 1132 provide process gases into the gas plenum 1138 first via the top baffle 1136. The gas showerhead 1134 includes a plurality of conduits that allow the process gases to flow through. The gas plenum 1138 and the showerhead 1134 are configured to improve an axisymmetric flow pattern of process gases into the process region 1146.

The processing chamber 1100 further includes a heating unit 1122 coupled with the susceptor 1120. The heating unit 1122 includes heating elements 1109 disposed in a body 1108. According to an embodiment, the heating elements 1109 are resistive heaters. The heating unit 1122 may also include bias electrodes configured to provide bias voltage to the susceptor 1120. The bias electrodes can increase the kinetic energy of the radical/ions in the process gases and add directionality. The heating unit 1122 and the susceptor 1120 may be coupled with a lifter 1144 configured to lift up and lower down the susceptor 1120 and the heating unit 1122. The heating unit 1122 is configured to adjust the temperature of the substrate within a predetermined range, such as 0 to 1,500° C., 100 to 800° C., 100 to 700° C., 100 to 600° C., 100 to 500° C., 100 to 400° C., or other suitable temperature ranges.

As the substrate 1110 has a low temperature during EPI growth, the processing chamber 1100 includes a plurality of plasma sources 1126, 1128, 1130 disposed at various locations of the processing chamber 1100 to energize the process gases. After energization, the reactants of the process gases, such as radicals and ions, have a high energy that can increase both growth rate and uniformity of deposited materials. As shown in FIG. 11, a plasma source 1130 may be disposed at a top surface of the lid 1124, and/or another plasma source 1126 is disposed around the side walls of the lid 1124. The plasma sources 1130 and 1126 are operable to energize the process gases above the showerhead 1134, e.g. within the gas plenum 1138. Another plasma source 1128 may disposed along side walls 1102 and is operable to energize the process gases between the showerhead 1134 and the susceptor 1120. Furthermore, a remote plasma source 1152 may be disposed outside the lid 1124 and operable to energize the process gases prior to entering the plenum 1138. The plasma sources 1152, 1130, 1126, and 1128 can be controlled independently or collectively by the controller 190 depicted in FIG. 1.

Benefits of the present disclosure include low temperature (e.g., 500 degrees Celsius or lower) processing, fast processing, and selective processing. As an example, the present disclosure facilitates low temperature etching that is fast and is selective. As another example, the present disclosure facilitates low temperature deposition that is fast and is selective. The subject matter can form phosphorus doped silicon layers having a high phosphorus dopant concentration. The dopant concentration facilitates selectively growing silicon layers on silicon window(s) of the substrate relative to dielectric portions of the substrate. For example, the first etch process facilitates selectively etching amorphous portions of doped silicon layers relative to portions of the doped silicon layers on the silicon window(s), and the second etch process facilitates fast etching at low temperatures. Benefits also include reduced dopant diffusion, increased throughput, and enhanced device performance (such as high conductivity).

It is contemplated that one or more aspects disclosed herein may be combined. As an example, one or more aspects, features, components, operations, and/or properties of the processing chamber 100, the processing chamber 1100, the film structure 200, doped semiconductor epitaxial layers 204, the method 300, the co-flow embodiment 400, the sequential embodiment 500, the device 600, the parameters of FIG. 8, the parameters of FIG. 9, and/or the parameters of FIG. 10 may be combined. As an example, operation parameters described for the co-flow embodiment 400 can be used for the sequential embodiment 500, and operation parameters described for the sequential embodiment 500 can be used in the co-flow embodiment 400. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A method of substrate processing, comprising:
flowing a deposition composition over a substrate within a processing volume, the deposition composition comprising a deposition precursor;
flowing an etchant composition over the substrate, the etchant composition comprising an etchant precursor flowed at a flow rate that is a ratio of 11:1 or less relative to a flow rate of the deposition precursor;
supplying a plasma to the processing volume;
depositing one or more layers on the substrate using the deposition composition; and
etching the one or more layers using the etchant composition.

2. The method of claim 1, wherein at least part of the flowing of the deposition composition and at least part of the flowing of the etchant composition occurs simultaneously.

3. The method of claim 1, wherein the flowing of the deposition composition and the flowing of the etchant composition occur sequentially with respect to each other.

4. The method of claim 1, wherein the etchant composition is substantially free of hydrogen gas.

5. The method of claim 4, wherein a ratio of a flow rate of hydrogen gas in the etchant composition to the flow rate of the etchant precursor is 1:10 or less.

6. The method of claim 1, wherein the supplying of the plasma comprises generating the plasma in a capacitive coupled plasma (CCP) manner within the processing volume.

7. The method of claim 1, wherein the ratio of the flow rate of the etchant precursor to the flow rate of the deposition precursor is greater than or equal to 2:1 and less than or equal to 5:1.

8. The method of claim 7, wherein the ratio of the flow rate of the etchant precursor to the flow rate of the deposition precursor is within a range of 2:1 to 3:1.

9. A method of substrate processing, comprising:
flowing a deposition composition over a substrate within a processing volume;
flowing an etchant composition over the substrate, the etchant composition substantially free of hydrogen gas;
supplying a plasma to the processing volume;
depositing one or more layers on the substrate using the deposition composition; and
etching the one or more layers using the etchant composition.

10. The method of claim 9, wherein at least part of the flowing of the deposition composition and at least part of the flowing the etchant composition occurs simultaneously.

11. The method of claim 9, wherein the etchant composition and the deposition composition are activated by the plasma.

12. The method of claim 9, wherein a ratio of a flow rate of hydrogen gas in the etchant composition to a flow rate of an etchant precursor in the etchant composition is 1:10 or less.

13. The method of claim 9, wherein the supplying of the plasma comprises generating the plasma in a capacitive coupled plasma (CCP) manner within the processing volume.

14. The method of claim 9, wherein a deposition precursor of the deposition composition includes a silane gas and an etchant precursor of the etchant composition includes hydrogen chloride gas.

15. The method of claim 14, wherein the etchant precursor is flowed at a flow rate that is a ratio of 11:1 or less relative to a flow rate of the deposition precursor.

16. A non-transitory computer-readable medium storing instructions that, when executed by a processor, cause a plurality of operations to be conducted, the plurality of operations comprising:
flowing a deposition composition over a substrate within a processing volume, the deposition composition comprising a deposition precursor;
flowing an etchant composition over a substrate, the etchant composition comprising an etchant precursor flowed at a flow rate that is a ratio of 11:1 or less relative to a flow rate of the deposition precursor; and
supplying a plasma to the processing volume.

17. The non-transitory computer-readable medium of claim 16, wherein at least part of the flowing of the deposition composition and at least part of the flowing of the etchant composition occurs simultaneously.

18. The non-transitory computer-readable medium of claim 16, wherein the flowing of the deposition composition and the flowing of the etchant composition occurs sequentially with respect to each other.

19. The non-transitory computer-readable medium of claim 16, wherein the supplying of the plasma comprises generating the plasma in a capacitive coupled plasma (CCP) manner within the processing volume.

20. The non-transitory computer-readable medium of claim 16, wherein the ratio of the flow rate of etchant precursor to the flow rate of the deposition precursor is greater than or equal to 2:1 and less than or equal to 5:1.
